(19) United States
(12) Patent Application Publication
(10) Pub. No.: US 2023/0420277 A1
(43) Pub. Date: Dec. 28, 2023

(54) RECIPE PROPOSAL DEVICE AND RECIPE PROPOSAL METHOD

(71) Applicant: Panasonic Intellectual Property Management Co., Ltd., Osaka (JP)

(72) Inventors: Akihiro ITOU, KYOTO (JP); Hiroshi SHIROUZU, SHIGA (JP); Atsushi HARIKAI, OSAKA (JP)

(21) Appl. No.: 18/328,955

(22) Filed: Jun. 5, 2023

(30) Foreign Application Priority Data
Jun. 28, 2022 (JP) 2022-103983

(51) Int. Cl. H01L 21/67

(52) U.S. Cl. CPC H01L 21/67253

(57) ABSTRACT

Disclosed is a recipe proposal device 10 including: an input section 11 for inputting a target information regarding a target shape of a substrate to be processed in a substrate processing apparatus; a recipe proposal section 12 that proposes a process recipe used in the substrate processing apparatus in order to form the target shape, based on the target information; a calculation section 13 that calculates a prediction information regarding a predicted shape when the substrate is processed in the substrate processing apparatus using the process recipe; and a display section 14 that displays the target information and the prediction information.

### CROSS REFERENCE TO RELATED APPLICATION

The present application is based on and claims priority under 35 U.S.C. §119 with respect to the Japanese Patent Application No. 2022-103983 and filed on Jun. 28, 2022, of which entire content is incorporated herein by reference into the present application.

### TECHNICAL FIELD

The present disclosure relates to a recipe proposal device and a recipe proposal method.

### BACKGROUND OF THE INVENTION

Conventionally, a substrate processing apparatus for processing a substrate has been known (e.g., Patent Literature 1: JP2018-137405A). The substrate processing apparatus of Patent Literature 1 is a plasma processing apparatus for plasma-processing a substrate, and the plasma processing of a substrate is performed according to the processing conditions which correspond to respective processing steps (e.g., flow rate of raw material gas, applied electric power, processing time). Such processing conditions are usually stored as a process recipe (hereinafter sometimes simply referred to as a recipe) in a memory unit included in the substrate processing apparatus. The substrate processing apparatus reads the recipe from the memory unit, and controls each component based on the recipe.

Conventionally, creating a recipe suited for a processing shape desired to be realized by processing a substrate (hereinafter, a target shape) has required a relatively large number of man-hours. For example, when a recipe suited for a target shape is created by repeating the adjustment of processing conditions included in the recipe and the actual processing, actual processing must be performed multiple times. Moreover, evaluating whether or not the created recipe is appropriate is not easy. Under such circumstances, one object of the present disclosure is to propose a recipe that corresponds to a target shape and can be easily evaluated.

### SUMMARY OF THE INVENTION

One aspect according to the present disclosure relates to a recipe proposal device. The recipe proposal device includes: an input section for inputting a target information regarding a target shape of a substrate to be processed in a substrate processing apparatus; a recipe proposal section that proposes a process recipe used in the substrate processing apparatus in order to form the target shape, based on the target information; a calculation section that calculates a prediction information regarding a predicted shape when the substrate is processed in the substrate processing apparatus using the process recipe; and a display section that displays the target information and the prediction information.

Another aspect according to the present disclosure relates to a recipe proposal method. The recipe proposal method is for proposing a recipe using a recipe proposal device, and includes: a first step in which an input section receives an input of a target information regarding a target shape of a substrate to be processed in a substrate processing apparatus; a second step in which a recipe proposal section proposes a process recipe used in the substrate processing apparatus in order to form the target shape, based on the target information; a third step in which a calculation section calculates a prediction information regarding a predicted shape when the substrate is processed in the substrate processing apparatus using the process recipe; and a fourth step in which a display section displays the target information and the prediction information.

According to the present disclosure, it is possible to propose a recipe that corresponds to a target shape and can be easily evaluated.

### BRIEF DESCRIPTION OF THE DRAWINGS

FIG. 1 is a block diagram showing a configuration of an example of a recipe proposal device according to the present disclosure.

FIG. 2 shows an example of a screen for entering a target information, displayed on a display section.

FIG. 3 shows an example of a screen that displays a proposed recipe and a corrected recipe, displayed on a display section.

FIG. 4 shows an example of a screen that displays a target information, a prediction information, and a correction prediction information, displayed on a display section.

FIG. 5 shows another example of a screen that displays a target information, a prediction information, and a correction prediction information, displayed on a display section.

FIG. 6 is a flowchart of an example of a recipe proposal method according to the present disclosure.

### DETAILED DESCRIPTION OF THE INVENTION

Embodiments of a recipe proposal device and a recipe proposal method according to the present disclosure will be described below by way of examples. It is to be noted, however, that the present disclosure is not limited to the examples described below. In the description below, specific numerical values and materials are exemplified in some cases, but other numerical values and materials may be applied as long as the effects of the present disclosure can be achieved.

### (Recipe Proposal Device)

The recipe proposal device according to the present disclosure is a device that proposes a process recipe to be used in a substrate processing apparatus (e.g., plasma processing apparatus) in response to an input (e.g., user input), and makes a display that can be utilized for evaluation of the proposed process recipe. The recipe proposal device may be integrated with or separate from the substrate processing apparatus. The recipe proposal device includes an input section, a recipe proposal section, a calculation section, and a display section. The input section, the recipe proposal section, the calculation section, and the display section may be all integrated into one, or at least one of them may be separated. For example, the input section and the display section may be integrated into one and held by the user, while the recipe proposal section and the calculation section may be present in the cloud.

The input section is an element for inputting a target information regarding a target shape of a substrate to be processed in the substrate processing apparatus. The target shape may be, for example, a target shape of grooves to be formed on the substrate. The target information may be, for example, the values of dimensions of respective parts in the target shape. The dimensions of respective parts may be, for example, the depth, opening width, and bottom width of the grooves to be formed on the substrate. The input section may be, for example, an input field displayed on the display section.

The recipe proposal section proposes a process recipe (or a recipe) to be used in the substrate processing apparatus in order to form the target shape, based on the inputted target information. When the substrate processing apparatus is a plasma processing apparatus, the recipe may include parameters, such as the flow rate of raw material gas, the pressure in the processing chamber, the applied electric power, and the processing time. The recipe proposal section may determine a candidate value for each of these parameters, based on the inputted target information. This determination can be made, for example, by selecting a recipe suited for the target shape from a database regarding the relationship between the recipe and the processing shape, by selecting multiple recipes suited for the target shape from the above database and interpolating the parameters in the above multiple recipes, or by calculating from a learned model established through machine learning. The recipe proposal section may be a functional section to be realized by execution of a predetermined program by an arithmetic unit included in the recipe proposal device.

The calculation section calculates a prediction information regarding a predicted shape when the substrate is processed in the substrate processing apparatus using the process recipe. This calculation can be made, for example, by calculating from a model equation established based on experimental data (e.g., a polynomial equation representing the relationship between the processing shape and respective parameters). The predicted shape may be, for example, a predicted shape of grooves to be formed on a substrate. The prediction information may be, for example, the values of dimensions of respective parts in the predicted shape. The dimensions of respective parts may be, for example, the depth, opening width, and bottom width of the grooves to be formed on the substrate. The calculation section may be a functional section to be realized by execution of a predetermined program by an arithmetic unit included in the recipe proposal device.

The display section displays the target information and the prediction information. The display section may or may not simultaneously display the target information and the prediction information. The display section may numerically display the target information and the prediction information. In addition thereto, the display section may visually display the target shape and the predicted shape. The display section may include a display panel included in the recipe proposal device.

As described above, in the recipe proposal device according to the present disclosure, a recipe with the purpose of realizing a target shape is proposed by the recipe proposal section, based on the target information inputted via the input section. The recipe thus proposed (hereinafter sometimes referred to as the “proposed recipe”) is provided for the calculation of a prediction information by the calculation section. Since the target information and the prediction information are displayed on the display section, the user can easily evaluate the proposed recipe while checking the display.

The display section may display the target information and the prediction information on the same screen. According to this configuration, the user can more easily check the display. It is preferable that the display section simultaneously displays the target information and the prediction information on the same screen.

The calculation section may calculate the prediction information, based on a processing model representing the relationship between a recipe parameter included in the process recipe and a processing shape in the substrate processing apparatus. The processing model may be, for example, a model equation representing the relationship between the recipe parameter and the processing shape, which is established based on experimental data. When the substrate processing apparatus is a plasma processing apparatus, the recipe parameter may include the flow rate of raw material gas, the pressure in the processing chamber, the applied electric power, and the processing time. The processing model may be a learned model established through machine learning.

The recipe proposal section may refer to a database associating a plurality of the process recipes with respective processing shapes when the process recipes are used, and from the database, may extract and propose the process recipe which corresponds to the processing shape close to the target information. The database may be stored in a memory unit included in the substrate processing apparatus or in a device separate from the substrate processing apparatus (e.g., a server device). The processing shape close to the target shape may be, for example, among a plurality of processing shapes included in the above database, a processing shape whose error from the target shape (e.g., the accumulated value of errors of each dimension value) is the smallest.

The recipe proposal device may further include a decision section that receives an input regarding whether or not to adopt the process recipe proposed by the recipe proposal section. According to this configuration, the user can decide, via the decision section, for example, to adopt the proposed recipe. The decision section may include, for example, a recipe save instruction section which is for saving the proposed recipe in the memory unit and is displayed on the display section. In this case, inputting into the recipe save instruction section indicates the user's intention to adopt the proposed recipe, while not inputting into the recipe save instruction section indicates the user's intention not to adopt the proposed recipe.

The recipe proposal device may further include a modification section for modifying the process recipe proposed by the recipe proposal section. The calculation section may calculate a correction prediction information regarding a predicted shape when the substrate is processed in the substrate processing apparatus, using a corrected process recipe which is the process recipe after the modification (hereinafter sometimes simply referred to as a corrected recipe). The display section may display the target information and the correction prediction information. The modification section may include an input field for inputting the corrected recipe, and a recalculation instruction section for instructing a recalculation of the predicted shape based on the corrected recipe, each of which is displayed on the display section. According to this configuration, when not adopting the proposed recipe (the process recipe before modification), the user can input a corrected recipe and obtain a correction prediction information based on the corrected recipe. The user can then easily evaluate the corrected recipe, while checking the target information and the correction prediction information that are displayed on the display section. The display section may display the correction prediction information in place of the prediction information, or may display the correction prediction information in addition to the prediction information. In the latter case, the display section will display the target information, the prediction information, and the correction prediction information.

The display section may display the target information and the correction prediction information on the same screen. According to this configuration, the user can check the display more easily. Preferably, the display section simultaneously displays the target information and the correction prediction information on the same screen. More preferably, the display section may simultaneously display the target information, the prediction information, and the correction prediction information on the same screen.

The recipe proposal device may further include a decision section that receives an input regarding whether or not to adopt the corrected process recipe. According to this configuration, the user can decide, via the decision section, for example, to adopt the corrected recipe. The decision section may include, for example, a recipe save instruction section which is for saving the corrected recipe in the memory unit and is displayed on the display section. In this case, inputting into the recipe save instruction section indicates the user's intention to adopt the corrected recipe, while not inputting into the recipe save instruction section indicates the user's intention not to adopt the corrected recipe.

(Recipe Proposal Method) The recipe proposal method according to the present disclosure is a method for proposing a process recipe to be used in a substrate processing apparatus (e.g., plasma processing apparatus) in response to an input (e.g., a user input), and making a display necessary for evaluating the proposed process recipe. The recipe proposal method may be executed in the substrate processing apparatus or in a device separate from the substrate processing apparatus (e.g., a personal computer, a tablet terminal). The recipe proposal method includes a first step, a second step, a third step, and a fourth step.

In the first step, an input section receives an input of a target information regarding a target shape of a substrate to be processed in the substrate processing apparatus. The target shape may be, for example, a target shape of grooves to be formed on the substrate. The target information may be, for example, the values of dimensions of respective parts in the target shape. The dimensions of respective parts may be, for example, the depth, opening width, and bottom width of the grooves to be formed on the substrate.

In the second step, a recipe proposal section proposes a process recipe (or a recipe) used in the substrate processing apparatus in order to form the target shape, based on the target information. When the substrate processing apparatus is a plasma processing apparatus, the recipe may include parameters, such as the flow rate of raw material gas, the pressure in the processing chamber, the applied electric power, and the processing time. In the second step, a candidate value for each of these parameters may be determined, based on the target information inputted in the first step. This determination can be made, for example, by using the database as mentioned above.

In the third step, a calculation section calculates a prediction information regarding a predicted shape when the substrate is processed in the substrate processing apparatus using the process recipe. This calculation can be made, for example, by using the model equation as mentioned above. The predicted shape may be, for example, a predicted shape of grooves to be formed on a substrate. The prediction information may be, for example, the values of dimensions of respective parts in the predicted shape. The dimensions of respective parts may be, for example, the depth, opening width, and bottom width of the grooves to be formed on the substrate.

In the fourth step, a display section displays the target information and the prediction information. In the fourth step, the target information and the prediction information may or may not be simultaneously displayed. In the fourth step, the target information and the prediction information may be numerically displayed. In addition thereto, in the fourth step, the target shape and the predicted shape may be visually displayed. In the fourth step, the above display may be made via a display panel.

As described above, in the recipe proposal method according to the present disclosure, based on the target information inputted in the first step, a recipe with the purpose of realizing a target shape is proposed in the second step. The recipe thus proposed (proposed recipe) is provided for calculation of a prediction information in the third step. Since the target information and the prediction information are displayed in the fourth step, the user can easily evaluate the proposed recipe while checking the display.

In the fourth step, the display section may display the target information and the prediction information on the same screen. According to this configuration, the user can more easily check the display. In the fourth step, it is preferable that the display section simultaneously displays the target information and the prediction information on the same screen.

In the third step, the calculation section may calculate the prediction information, based on a processing model representing the relationship between a recipe parameter included in the process recipe and a processing shape in the substrate processing apparatus.

In the second step, the recipe proposal section may refer to a database associating a plurality of the process recipes with respective processing shapes when the process recipes are used, and from the database, may extract and propose the process recipe which corresponds to the processing shape close to the target information.

The recipe proposal method may further include a fifth step in which a decision section receives an input regarding whether or not to adopt the process recipe proposed in the second step. According thereto, the user can decide, in the fifth step, for example, to adopt the proposed recipe. In the fifth step, for example, the above input may be received via a recipe save button which is for saving the proposed recipe in a memory unit and is displayed on the display panel.

The recipe proposal method may further include: a sixth step in which a modification section accepts a modification of the process recipe proposed in the second step; a seventh step in which the calculation section calculates a correction prediction information regarding a predicted shape when the substrate is processed in the substrate processing apparatus using a corrected process recipe which is the process recipe after the modification; and an eighth step in which the display section displays the target information and the correction prediction information. In the sixth step, the modification may be accepted via an input field for inputting the corrected recipe, and a recalculation instruction button for instructing a recalculation of the predicted shape based on the corrected recipe, each of which is displayed on the display panel. According to this configuration, when not adopting the proposed recipe (the process recipe before modification), the user can input a corrected recipe and obtain a correction prediction information based on the corrected recipe. The user can then easily evaluate the corrected recipe, while checking the target information and the correction prediction information that are displayed in the eighth step. In the eighth step, the correction prediction information may be displayed in place of the prediction information, or the correction prediction information may be displayed in addition to the prediction information. In the latter case, in the eighth step, the target information, the prediction information, and the correction prediction information will be displayed.

In the eighth step, the display section may display the target information and the correction prediction information on the same screen. According thereto, the user can check the display more easily. In the eighth step, it is preferable that the target information and the correction prediction information are simultaneously displayed on the same screen. More preferably, in the eighth step, the target information, the prediction information, and the correction prediction information the display section may be simultaneously displayed on the same screen.

The recipe proposal method may further include a ninth step in which a decision section receives an input regarding whether or not to adopt the corrected process recipe. According thereto, the user can decide, in the ninth step, for example, to adopt the corrected recipe. In the ninth step, for example, the above input may be received via a recipe save button which is for saving the corrected recipe in a memory unit and is displayed on the display panel.

As described above, according to the present disclosure, a recipe that corresponds to the target shape and can be easily evaluated can be proposed. Also, according to the present disclosure, the user can easily make a decision on whether or not to adopt the proposed recipe. Furthermore, according to the present disclosure, the user can create a corrected recipe when not adopting the proposed recipe, and can easily make an evaluation on the latter.

In the following, examples of the recipe proposal device and the recipe proposal method according to the present disclosure will be specifically described with reference to the drawings. To the components and processes of the below-described examples of recipe proposal device and the recipe proposal method, the components and processes as described above can be applied. The components and processes of the below-described examples of the recipe proposal device and the recipe proposal method can be modified based on the description above. The matters as described below may be applied to the above embodiments. Of the components and processes of the below-described examples of the recipe proposal device and the recipe proposal method, the components and processes which are not essential to the recipe proposal device and the recipe proposal method according to the present disclosure may be omitted. The figures below are schematic and not intended to accurately reflect the shape and the number of the actual members.

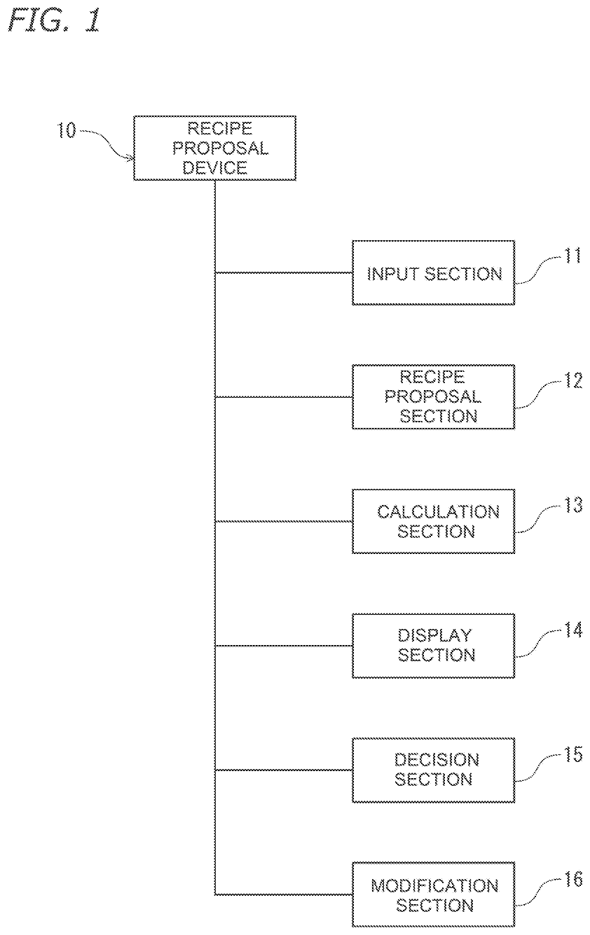

A recipe proposal device 10 of the present embodiment is a device that proposes a recipe to be used in a plasma processing apparatus (not shown) in response to a user input, and makes a display that can be utilized for evaluation of the proposed process. The recipe proposal device 10 is separate from the plasma processing apparatus, but is not limited thereto. As shown in FIGS. 1 to 5, the recipe proposal device 10 includes an input section 11, a recipe proposal section 12, a calculation section 13, a display section 14, a decision section 15, and a modification section 16.

Although not shown, the plasma processing apparatus has a processing chamber in which plasma processing of a substrate is performed, a high-frequency power source that supplies a high-frequency power for generating a plasma in the processing chamber, a raw material gas source that supplies a raw material gas into the processing chamber, a pressure regulation means that regulates the pressure in the processing chamber, a memory unit that stores a recipe used for plasma processing, and a control unit that controls each component based on the recipe. Alternatively, the memory unit and the control unit may be provided in a device separate from the plasma processing apparatus. The recipe proposal device 10 is communicable with the plasma processing apparatus.

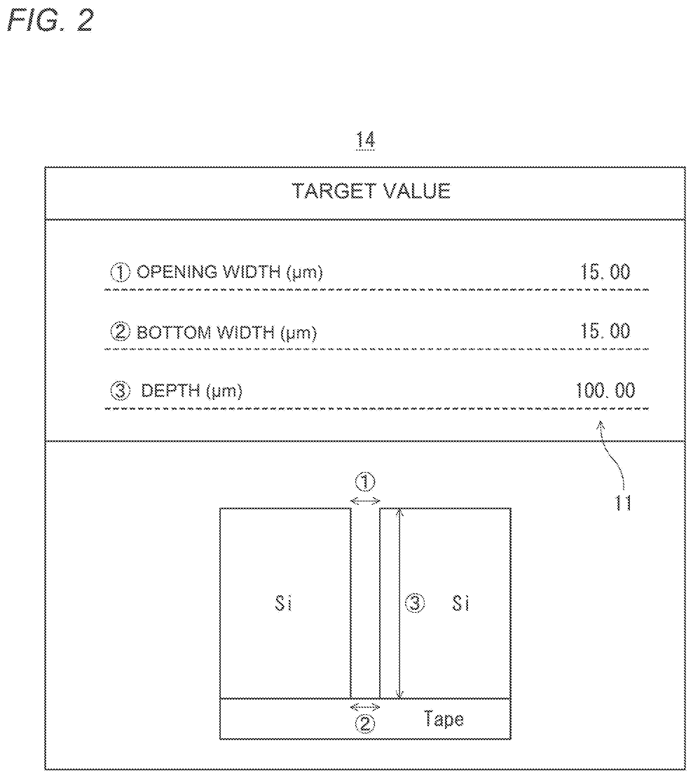

The input section 11 is an element for inputting a target information regarding a target shape of the substrate to be processed in the plasma processing apparatus, and is constituted of an input field (see FIG. 2) displayed on the display section 14. The target shape is a target shape of grooves to be formed on the substrate. The target information includes the values of dimensions of respective parts of the target shape, specifically, the depth, opening width, and bottom width of the grooves to be formed on the substrate. The user can input the target information into the recipe proposal device 10, via the input section 11.

The recipe proposal section 12 proposes a recipe to be used in the plasma processing apparatus in order to form the target shape, based on the inputted target information. The proposed recipe includes parameters, for example, in each step of the Bosch process (i.e., protective film deposition step, protective film removal step, and etching step), such as the flow rate of raw material gas, the pressure in the processing chamber, the applied electric power, the processing time, and the number of cycles. The recipe proposal section 12 determines a candidate value for each of these parameters, based on the inputted target information. The recipe proposal section 12, for example, refers to a database associating a plurality of recipes with respective processing shapes when the recipes are used, and from the database, extracts and proposes the process recipe which corresponds to the processing shape close to the target information, thereby to determine a candidate value for each of these parameters.

The calculation section 13 calculates a prediction information regarding a predicted shape when the substrate is processed in the substrate processing apparatus using the proposed recipe. The calculation section 13 calculates the prediction information, based on a processing model (e.g., a model equation established based on experimental data) that represents a relationship between the parameters included in the proposed recipe and the processing shape in the plasma processing apparatus. The predicted shape is a predicted shape of grooves to be formed on the substrate. The prediction information includes the values of dimensions of respective parts in the predicted shape, specifically, the depth, opening width, and bottom width of the grooves to be formed on the substrate.

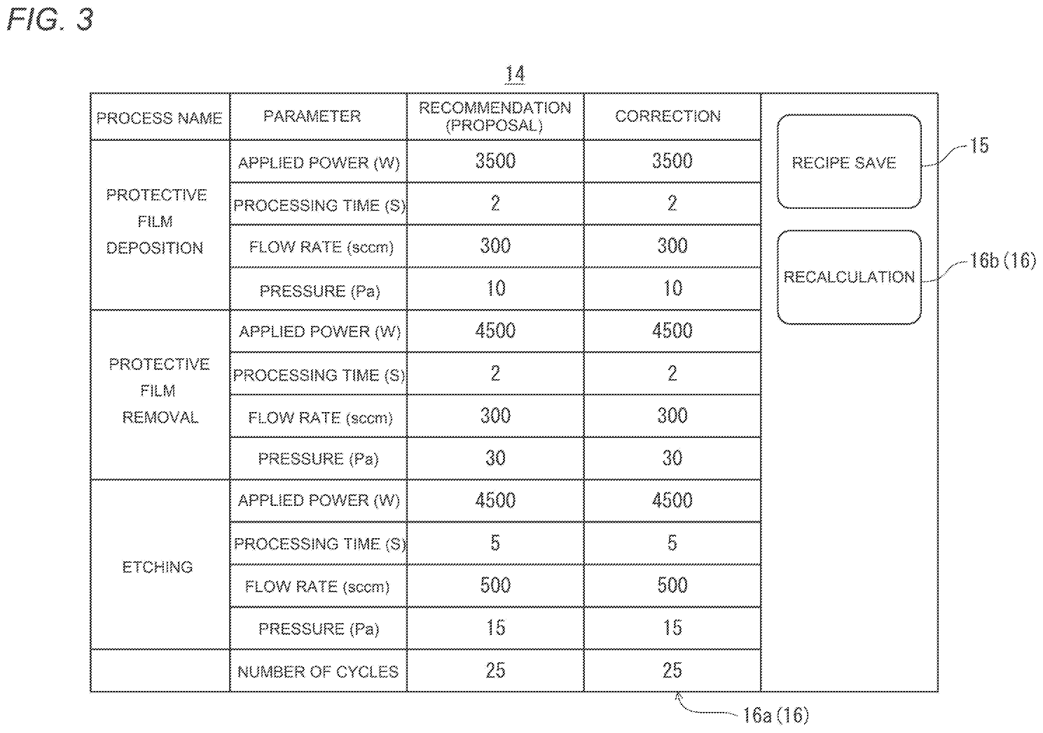

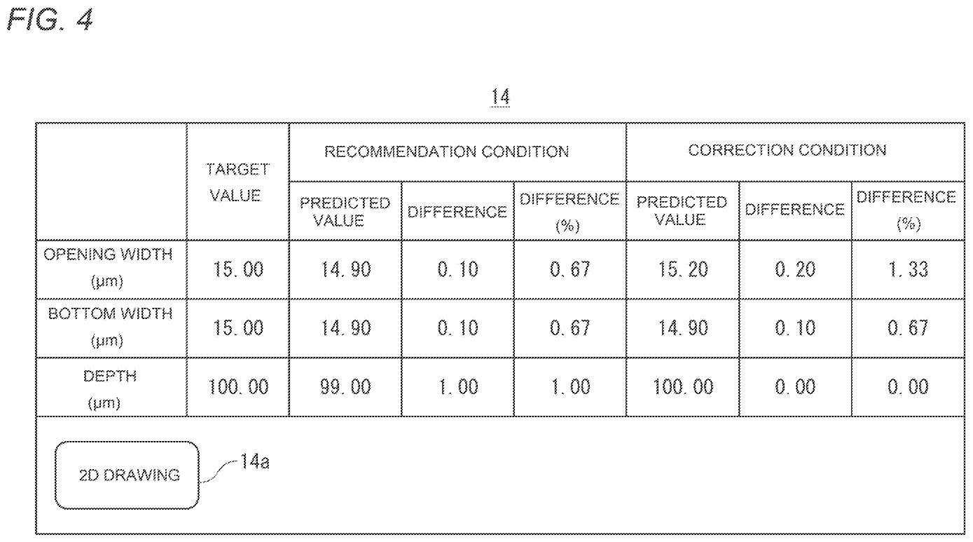

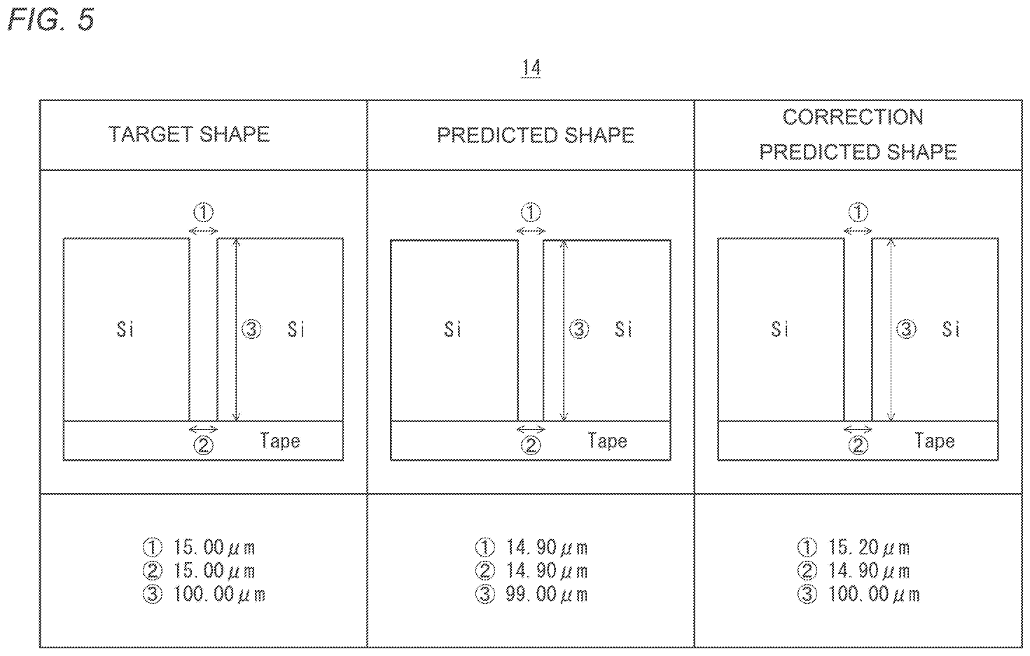

The display section 14 has a display panel (see FIGS. 2 to 5) provided in the recipe proposal device 10. The display section 14 displays the proposed recipe as shown in FIG. 3. The display section 14 simultaneously displays the target information and the prediction information on the same screen (i.e., display panel), as shown in FIG. 4. In addition thereto, the display section 14 simultaneously displays a later-described correction prediction information, as needed, on the same screen. The display section 14 may display these information numerically and visually, according to a user's instruction (e.g., an instruction via a 2D drawing button 14a in FIG. 4), as shown in FIG. 5. The user can easily evaluate the proposed recipe while checking the display. The display section 14 may or may not simultaneously display at least two of the displays in FIGS. 3 to 5 (e.g., the displays in FIGS. 3 and 4), on the same screen.

The decision section 15 is an element for receiving an input regarding whether or not to adopt the proposed recipe, and is constituted of a recipe save button (see FIG. 3) displayed on the display section 14. The user, via the decision section 15, can perform an input regarding whether or not to adopt the proposed recipe, to the recipe proposal device 10. If an input indicating to adopt the proposed recipe is inputted into the decision section 15, the proposed recipe is stored in the memory unit of the plasma processing apparatus by the recipe proposal device 10.

The modification section 16 is an element for modifying the proposed recipe (or for inputting a corrected recipe). The modification section 16 includes, as shown in FIG. 3, an input field 16a for inputting a corrected recipe, and a recalculation button 16b for instructing a recalculation of the predicted shape based on the corrected recipe, each of which is displayed on the display section 14. When not adopting the proposed recipe, the user can input a corrected recipe, via the modification section 16, into the recipe proposal device 10.

The above calculation section 13 further calculates a correction prediction information regarding a predicted shape when the substrate is processed in the substrate processing apparatus, using the corrected recipe. The calculation section 13 calculates a correction prediction information, based on a processing model representing the relationship between the parameters included in the corrected recipe and the processing shape in the plasma processing apparatus. The correction prediction information includes the depth, opening width, and bottom width of the grooves to be formed on the substrate.

The above decision section 15 further receives an input regarding whether or not to adopt the corrected recipe. The user, via the decision section 15, can perform an input regarding whether or not to adopt the corrected recipe, to the recipe proposal device 10. If an input indicating to adopt the corrected recipe is inputted into the decision section 15, the corrected recipe is stored in the memory unit of the plasma processing apparatus by the recipe proposal device 10.

### (Recipe Proposal Method)

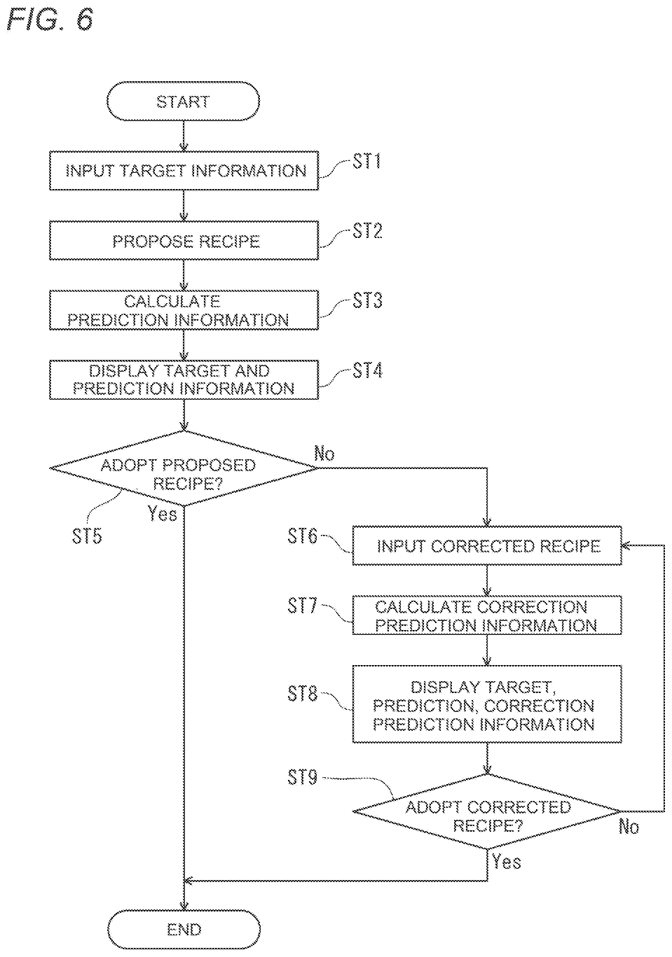

Next, a recipe proposal method using the above recipe proposal device 10 will be described with reference to FIG. 6. As shown in FIG. 6, the recipe proposal method of the present embodiment includes a first step ST1, a second step ST2, a third step ST3, a fourth step ST4, a fifth step ST5, a sixth step ST6, a seventh step ST7, an eighth step ST8, and a ninth step ST9.

In the first step ST1, via the input section 11, an input of a target information regarding a target shape of a substrate to be processed in a plasma processing apparatus is received. Upon completion of the input of the target information by the user, the process proceeds to the second step ST2.

In the second step ST2, the recipe proposal section 12 proposes a recipe to be used in the plasma processing apparatus in order to form the target shape, based on the target information. Here, a database associating a plurality of recipes with respective processing shapes when the recipes are used is referred to, and from the database, the recipe which corresponds to the processing shape close to the target information is extracted and proposed. The process continues to the third step ST3.

In the third step ST3, the calculation section 13 calculates a prediction information regarding a predicted shape when the substrate is processed in the substrate processing apparatus. Here, the prediction information is calculated based on a processing model representing the relationship between a recipe parameter included in the proposed recipe and a processing shape in the plasma processing apparatus. The process continues to the fourth step ST4.

In the fourth step ST4, via the display section 14, the target information and the prediction information are displayed on the same screen. This allows the user to easily evaluate the proposed recipe while checking the display. The process continues to the fifth step STS.

In the fifth step ST5, via the decision section 15, an input regarding whether or not to adopt the proposed recipe is received. If an input indicating to adopt the proposed recipe is received (if Yes), the proposed recipe is stored in the memory unit, and a series of processing ends. On the other hand, if an input indicating not to adopt the proposed recipe is received (if No), the proposed recipe is not stored in the memory unit, and the process proceeds to the sixth step ST6.

In the sixth step ST6, via the modification section 16, a modification to the proposed recipe (or an input of a corrected recipe) is accepted. Upon completion of the input of the corrected recipe by the user, the process proceeds to the seventh step ST7.

In the seventh process ST7, the calculation section 13 calculates a correction prediction information regarding a predicted shape when the substrate is processed in the plasma processing apparatus using the corrected recipe. Here, the correction prediction information is calculated based on a processing model representing the relationship between a recipe parameter included in the corrected recipe and a processing shape in the plasma processing apparatus. The process continues to the eighth step ST8.

In the eighth step ST8, via the display section 14, the target information, the prediction information, and the correction prediction information are displayed on the same screen. This allows the user to easily evaluate the corrected recipe while checking the display. The process continues to the ninth step ST9.

In the ninth step ST9, via the decision section 15, an input regarding whether or not to adopt the corrected recipe is received. If an input indicating to adopt the corrected recipe is received (if Yes), the corrected recipe is stored in the memory unit, and a series of processing ends. On the other hand, if an input indicating not to adopt the corrected recipe is received (if No), the corrected recipe is not stored in the memory unit, and the process returns to the sixth step ST6. In the second and subsequent times of the sixth step ST6, a re-modification of the corrected recipe is accepted. Then, the steps from the sixth step ST6 to the ninth step ST9 are repeated until an input indicating to adopt the corrected recipe is received in the ninth step ST9.

Although preferred embodiments of the present disclosure have been described, the scope of the disclosure should not be limited by this description. For example, matters recited in two or more claims selected from a plurality of claims in the appended claims may be combined as long as no technical contradiction arises.

The present disclosure is applicable to a recipe proposal device and a recipe proposal method.

### REFERENCE NUMERALS

10: recipe proposal device
11: input section
12: recipe proposal section
13: calculation section
14: display section
   14a: 2D drawing button
15: decision section
16: modification section
   16a: input field
   16b: recalculation button

What is claimed is:

1. A recipe proposal device, comprising:
an input section for inputting a target information regarding a target shape of a substrate to be processed in a substrate processing apparatus;
a recipe proposal section that proposes a process recipe used in the substrate processing apparatus in order to form the target shape, based on the target information;
a calculation section that calculates a prediction information regarding a predicted shape when the substrate is processed in the substrate processing apparatus using the process recipe; and
a display section that displays the target information and the prediction information.

2. The recipe proposal device according to claim 1, wherein the display section displays the target information and the prediction information on a same screen.

3. The recipe proposal device according to claim 1, wherein the calculation section calculates the prediction information, based on a processing model representing a relationship between a recipe parameter included in the process recipe and a processing shape in the substrate processing apparatus.

4. The recipe proposal device according to claim 1, wherein the recipe proposal section refers to a database associating a plurality of the process recipes with respective processing shapes when the process recipes are used, and from the database, extracts and proposes the process recipe which corresponds to the processing shape close to the target information.

5. The recipe proposal device according to claim 1, further comprising a decision section that receives an input regarding whether or not to adopt the process recipe proposed by the recipe proposal section.

6. The recipe proposal device according to claim 1, further comprising a modification section for modifying the process recipe proposed by the recipe proposal section, wherein
the calculation section calculates a correction prediction information regarding a predicted shape when the substrate is processed in the substrate processing apparatus, using a
corrected process recipe which is the process recipe after the modification, and the display section displays the target information and the correction prediction information.

7. The recipe proposal device according to claim 6, wherein the display section displays the target information and the correction prediction information on a same screen.

8. The recipe proposal device according to claim 6, further comprising a decision section that receives an input regarding whether or not to adopt the corrected process recipe.

9. A recipe proposal method for proposing a recipe using a recipe proposal device, the method comprising:
a first step in which an input section receives an input of a target information regarding a target shape of a substrate to be processed in a substrate processing apparatus;
a second step in which a recipe proposal section proposes a process recipe used in the substrate processing apparatus in order to form the target shape, based on the target information;
a third step in which a calculation section calculates a prediction information regarding a predicted shape when the substrate is processed in the substrate processing apparatus using the process recipe; and
a fourth step in which a display section displays the target information and the prediction information.

10. The recipe proposal method according to claim 9, wherein in the fourth step, the display section displays the target information and the prediction information on a same screen.

11. The recipe proposal method according to claim 9, wherein in the third step, the calculation section calculates the prediction information, based on a processing model representing a relationship between a recipe parameter included in the process recipe and a processing shape in the substrate processing apparatus.

12. The recipe proposal method according to claim 9, wherein in the second step, the recipe proposal section refers to a database associating a plurality of the process recipes with respective processing shapes when the process recipes are used, and from the database, extracts and proposes the process recipe which corresponds to the processing shape close to the target information.

13. The recipe proposal method according to claim 9, further comprising a fifth step in which a decision section receives an input regarding whether or not to adopt the process recipe proposed in the second step.

14. The recipe proposal method according to claim 9, further comprising:
a sixth step in which a modification section accepts a modification of the process recipe proposed in the second step;
a seventh step in which the calculation section calculates a correction prediction information regarding a predicted shape when the substrate is processed in the substrate processing apparatus, using a corrected process recipe which is the process recipe after the modification; and
an eighth step in which the display section displays the target information and the correction prediction information.

15. The recipe proposal method according to claim 14, wherein in the eighth step, the display section displays the target information and the correction prediction information on a same screen.

16. The recipe proposal method according to claim 14, further comprising a ninth step in which a decision section receives an input regarding whether or not to adopt the corrected process recipe.
